(19) United States
(12) Patent Application Publication
(10) Pub. No.: US 2018/0324955 A1
(43) Pub. Date: Nov. 8, 2018

(54) NO-FLOW ADHESIVE FOR SECOND AND THIRD LEVEL INTERCONNECTS

(71) Applicant: Intel Corporation, Santa Clara, CA (US)

(72) Inventors: Mohit SOOD, Chandler, AZ (US); Huili XU, Chandler, AZ (US); Wei TAN, Chandler, AZ (US); Suriyakala RAMALINGAM, Chandler, AZ (US); Jan KRAJNIAK, Phoenix, AZ (US); Nish ANANTHAKRISHNAN, Chandler, AZ (US)

(21) Appl. No.: 15/777,893

(22) PCT Filed: Dec. 23, 2015
(86) PCT No.: PCT/US2015/000282

§ 371 Date: May 21, 2018

(51) Int. Cl. H05K 3/34; H01L 23/498; H05K 3/40; H05K 3/12; H05K 1/18; H05K 1/11

(52) U.S. Cl. CPC H05K 3/3436; H01L 23/49816; H05K 3/4007; H01L 24/16; H05K 3/3494; H05K 1/181; H05K 1/111; H05K 3/1283

(57) ABSTRACT

An apparatus is described. The apparatus includes a first planar board to second planar board interface. The first planar board to second planar board interface includes a reflowed solder electrical connection structure between the first and second boards and a no flow adhesive. The reflowed solder electrical connection structure includes a reflowed solder ball and a reflowed tinned pad.

### FIELD OF INVENTION

The field of invention pertains generally to the semiconductor arts, and, more specifically, to a no-flow adhesive for second and third level interconnects.

### BACKGROUND

The semiconductor arts has traditionally faced the challenge of attempting to integrate electronic functionality into as small a volume as possible. The packaging of electronic components therefore raises a number of challenges to effect incremental improvements in packing density of an overall electronic device or system. Such challenges appear not only in die to board attachments but also various board to board attachments as well.

### FIGURES

A better understanding of the present invention can be obtained from the following detailed description in conjunction with the following drawings, in which:

FIGS. 1a through 1d show a board to board attachment process;

FIGS. 2a through 2e show an improved board to board attachment process;

FIGS. 3a through 3f show another improved board to board attachment process;

FIGS. 4a through 4e show another improved board to board attachment process;

FIG. 5 shows a methodology of the improved board to board attachment processes;

FIG. 6 shows a computing system.

### DETAILED DESCRIPTION

Solder ball and solder paste mass reflow techniques may be used to attach a die to a package substrate, attach a package substrate to a planar board, or attach two planar boards together (e.g., in the case where a riser card is to be mounted to a lower motherboard). A planar board, as is understood in the art, is a multilayer structure composed of alternating dielectric and metal layers both of which are patterned to construct multiple electronic traces within the board. Vertical metal vias also typically exist within the dielectric layers to enable electrical connections between two different metal layers within the board.

In the case of mass reflow, generally, balls of solder on one of the structures are placed in contact with solder paste formed on contact pads on the other structure. The ambient temperature is then raised which melts the solder balls and the solder paste. The melted solder balls and paste form not only electrical connections, but also mechanical connections, between the two structures.

The inclusion of an adhesive material between the structures, dispersed amongst the solder balls and paste prior to mass reflow, may be used to reinforce the mechanical bond between the structures. An adhesive effectively acts as a glue that binds the two structures together along with the mechanical attachment formed by the melted solder balls and paste after mass reflow.

To simplify manufacturing processes that use adhesives, so called “no-flow” adhesives (e.g., no-flow epoxy, no-flow underfill, no-flow epoxy flux, etc.) may be preferable to “flow-able” adhesives. A no-flow adhesive is an adhesive having a high enough viscosity to behave more solid-like than a free-flowing liquid. That is, no-flow means something more viscous than a free-flowing, low-viscosity liquid. For example, the adhesive structurally behaves more like a syrup, a paste, a gel or a solid than a free flowing liquid. Various formulations of a no-flow adhesive may be sufficiently liquid in a first form to enable spraying of the adhesive, but, immediately after the spraying, the no-flow adhesive thickens and/or hardens and/or stops flowing due to its shear thinning/thickening properties so as to take on it no-flow characteristic.

Here, no-flow adhesives may be applied to a structure by being printed on the structure, sprayed on the structure, dipping the structure into a bath of the adhesive or dispending the adhesive. The higher viscosity no-flow adhesive, once applied to a particular structure, does not flow or otherwise migrate very readily from where it was first applied. As a consequence, the structure itself can be easily moved (e.g., rotated, flipped) after application of the no-flow adhesive without distorting the form and/or shape of the adhesive. Additionally or alternatively, once a no-flow adhesive is applied to a structure, the next processing procedure does not necessarily need to be performed immediately thereafter. By contrast, in the case of a flow-able adhesive, a next processing procedure may need to take place immediately after the flow-able adhesive is applied because the flow-able adhesive will migrate and/or change shape fairly quickly with time. Thus, no-flow adhesives provide for easier manufacturability and/or less burdensome manufacturability constraints. Additionally, if a flow-able adhesive is used, the joint has to be made first (solder to paste), followed by flowing the adhesive and subsequent cure. By contrast, if a no-flow adhesive is used, the joint may be made through the adhesive in its uncured state. The adhesive cures during reflow simultaneously leading to joint formation which eliminates the need for a subsequent flow-filling and separate adhesive cure sequence.

Adhesives may also be characterized as being “filler based” or “non filler based”. Filler based adhesives include some particulate material (e.g., silica) to give the adhesive some desired property over a filler-less adhesive. For example, a specific adhesive material with added filler may exhibit a lower coefficient of thermal expansion than the same adhesive material without the filler.

Although filler based no-flow adhesives have been successfully used in die to package substrate interconnects (first level interconnects), they have not heretofore been successfully applied to package to planar board interconnects (second level interconnects) or planar board to planar board interconnects (third level interconnects). That is, only filler-less no-flow adhesives have been successfully applied to package-to-board and board-to-board interconnects. As mentioned above, filler based no-flow adhesives are preferable to filler-less no-flow adhesives because they exhibit a smaller coefficient of thermal expansion. As such, they do not expand and contract as much as filler-less no-flow adhesives in response to thermal variations, and, as a consequence, are more reliable.

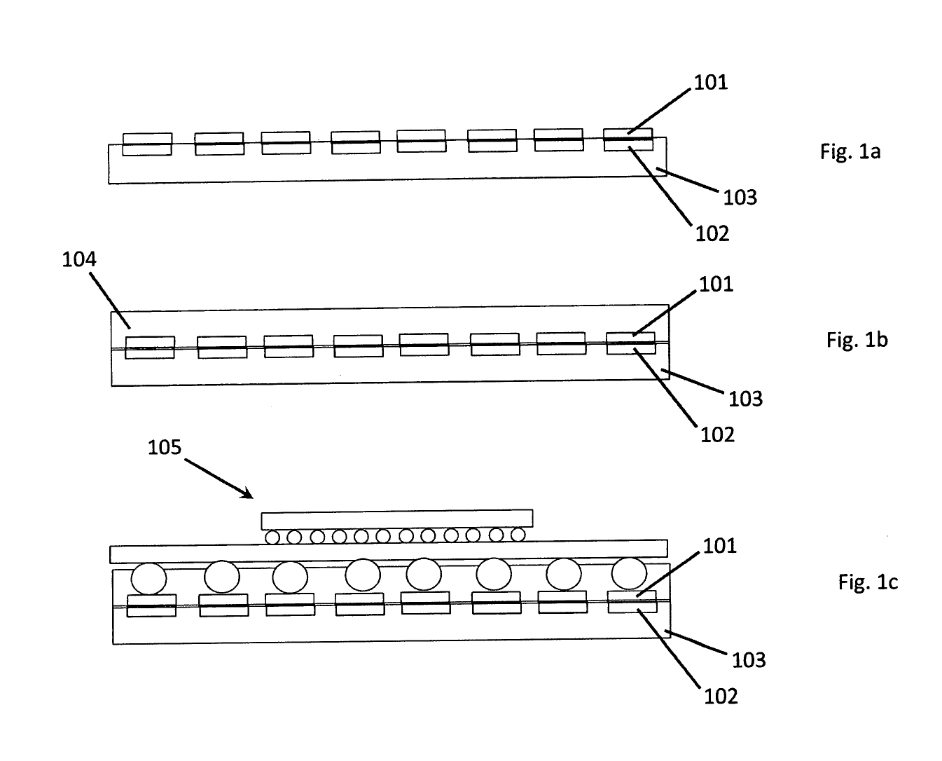

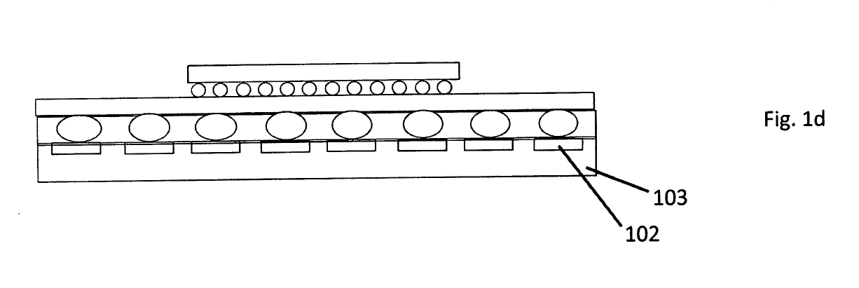

A problem with filler based no-flow adhesives when applied to second and third level interconnects has been the entrapment of filler material in the solder/pad interface during joint formation. FIGS. 1a through 1d demonstrate an exemplary filler based no-flow adhesive process that has not yielded acceptable results.

As observed in FIG. 1a, solder paste 101 is printed on the pads 102 of a planar board 103. As observed in FIG. 1b, a no-flow filler based adhesive 104 is applied to the surface of the planar board 103. As observed in FIG. 1c, a packaged semiconductor die 105 is mounted to the planar board 103 (for drawing simplicity reasons, the lid of the package semiconductor die is not shown). As observed in FIG. 1d the ambient temperature is raised to cause mass reflow of the solder balls of the packaged semiconductor die 105 and the solder paste.

Unfortunately, analysis has revealed that the filler particles of the adhesive 104 become trapped in the solder ball/paste/pad junction. The entrapment of the filler particles is believed to be a result of the solder paste 101 not fully covering the planar board pads 102. As a consequence, regions of the mother board pads 102 are directly exposed to the no-flow filler based adhesive 104. The exposed pad regions can be formed, e.g., from any misalignment in the printing of the solder paste 101 on the pad 102 (offset error) and/or if the shape of the solder paste 101 is too small (feature distortion) in combination with the relatively high viscosity of the solder paste (which inhibits its ability to flow over the surface of the pad 102) The direct contact between the adhesive 104 and the pad 102 causes the adhesive's fillers to migrate and become trapped at the pad 102 thereby degrading the quality of the mechanical connection between the package solder ball and the pad 102.

An additional failure mechanism may be the planar shape of the surface of the solder paste 101 that meets the solder ball. Here, the planar top surface area of the solder paste 101 causes a wider surface area of the solder paste 101 to meet with the solder ball, which, in an environment that includes the filler-based adhesive, permits the adhesive's filler to be intermixed/trapped in the ball/paste interface thereby corroding the quality of the ball/paste junction.

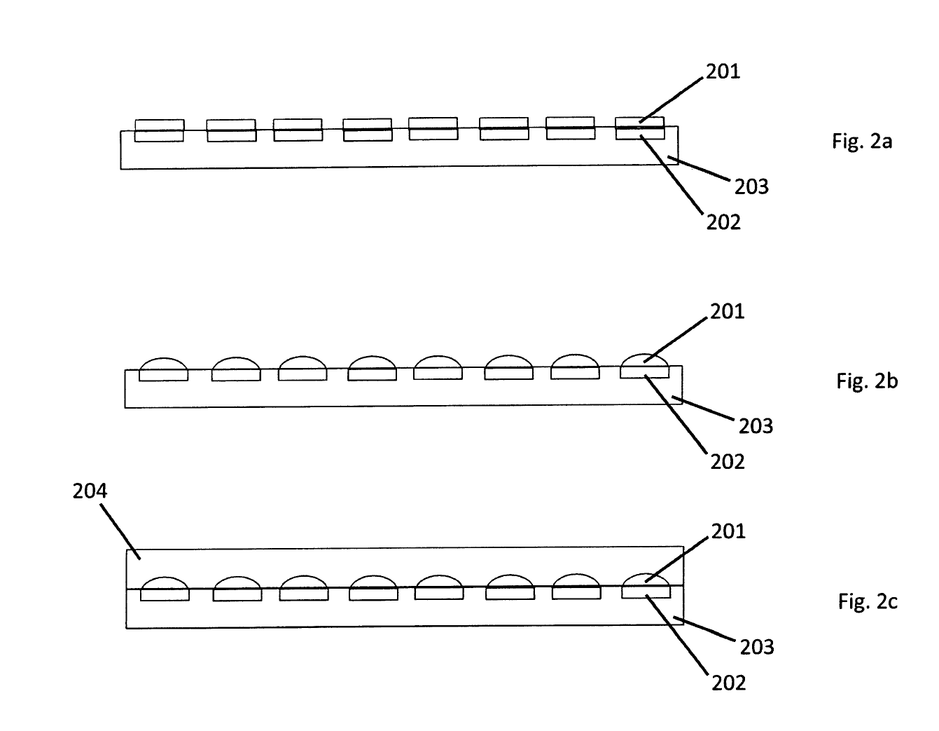

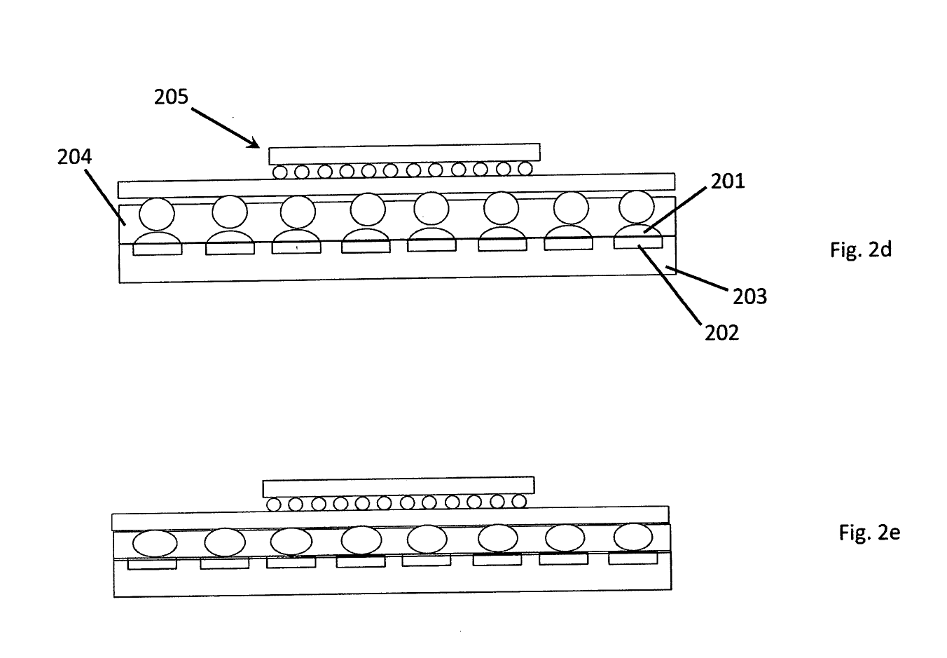

FIGS. 2a through 2e show an improved process that eliminates the aforementioned problems. As observed in FIG. 2a, solder paste 201 is first printed on the pads 102 of a planar board 103 by, e.g., photo-lithographic techniques. Alternatively, the solder paste 201 may be applied mechanically through a stencil. The solder paste 201 may comprise, e.g., tin or any alloy that includes tin.

As observed in FIG. 2b, the solder paste 201 is reflowed by elevating the ambient temperature. This particular procedure is distinctive from the process of FIGS. 1a through 1d which did not reflow the solder paste prior to the placement of the packaged semiconductor die. The reflowing of the solder paste 201, as depicted in FIG. 2b, results in the solder tinning the pads 202 on the planar board 203. The tinning of the pads 202 essentially covers the pads 202 with solder thereby substantially eliminating any exposed pad 202 regions. As such, unlike the process described above with respect to FIGS. 1a through 1d, some alignment offset (e.g., 30-40 μm) between the planar board pad 102 and the package ball may be permissible.

Additionally, the reflow of the solder paste 102 causes the solder surface to be more rounded. As a consequence, when the package is mounted to the board (as observed in FIG. 2d) the physical contact between the ball and solder is more like a point contact which is also distinctive from the planar solder paste 101 being flush against the ball as depicted in FIG. 1b. Thus, with the planar board pads 202 being substantially covered with solder and with a point contact between the reflowed solder paste and the package ball, there is minimal opportunity for adhesive filler to be trapped at the ball/solder/pad junction. As a consequence, more reliable ball junctions are formed.

Continuing with a discussion of the manufacturing process, as observed in FIG. 2c, a no-flow filler based adhesive 204 is applied to the surface of the planar board 203 after the solder paste is reflowed. As observed in FIG. 2d, a packaged semiconductor die 205 is mounted to the planar board 203. As observed in FIG. 2e, the ambient temperature is raised to cause mass reflow of the solder balls of the packaged semiconductor die 205 and the tinned pads 202 which mounts the packaged semiconductor die 205 to the planar board 203 (e.g., approximately 160-260° C.), e.g., 160-190° C. for “low temperature” alloy metallurgies (typically based on SnBi) and 220-260° C. for high temperature alloy metallurgies (typically based on Sn, Ag, Cu)). As described at length above, the reflow of the solder balls does not substantially result in filler material being trapped in the ball/solder/pad junction.

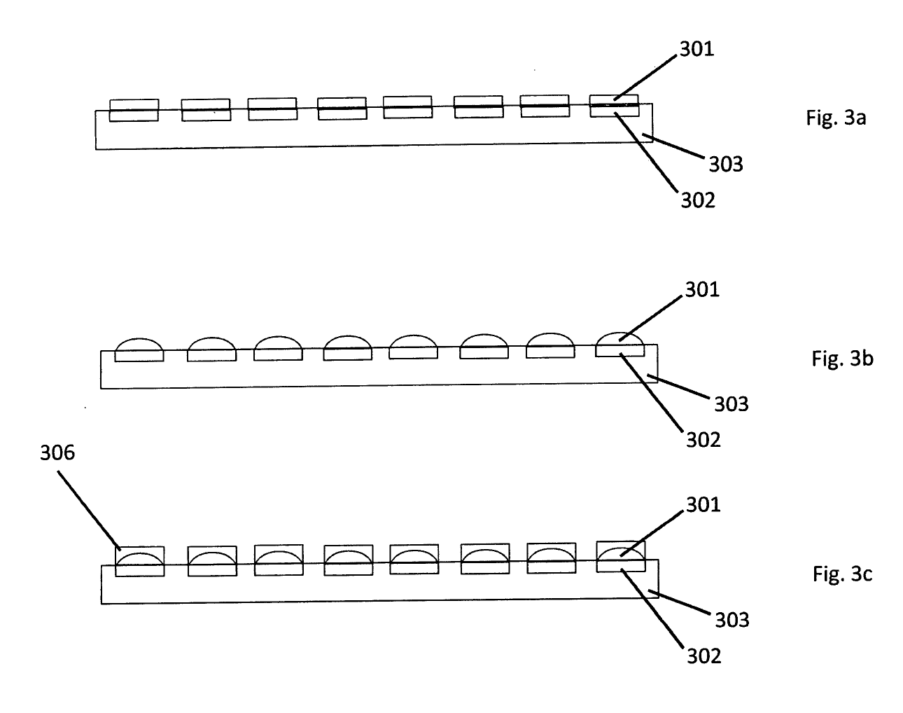

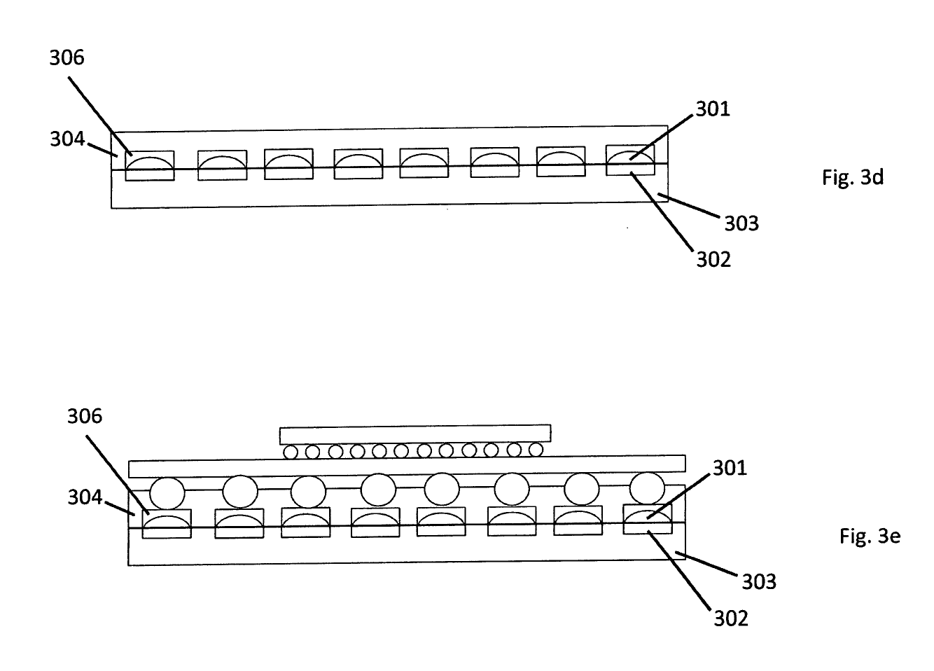

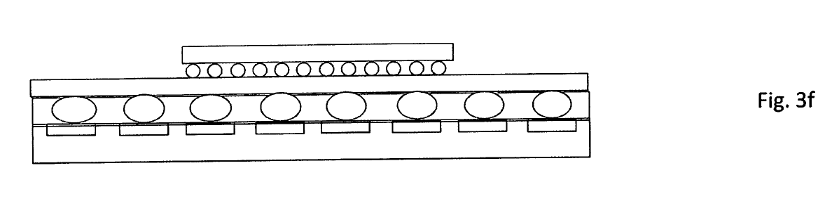

FIGS. 3a through 3f show another alternative embodiment in which, after the solder paste 301 is reflowed after it is first deposited (as observed in FIG. 3b), a layer of flux/no flow adhesive 306 is printed on the tinned mother board pads 302 as observed in FIG. 3c. The process then follows as depicted in FIGS. 3d through 3f consistently with the process of FIGS. 2c through 2e. The addition of the flux 306 on the tinned pads 302 helps to improve the solder joint formed between the package ball and tinned pad.

Regarding the use or lack thereof of an added flux, in reference to the processes of FIGS. 2a through 2e and FIGS. 3a through 3f, joints may be difficult to form if a no flow adhesive without fluxing ability is used by itself. That is, a no flow adhesive with fluxing ability can form good joints by itself, or a no flow adhesive without fluxing ability but with added flux can form good joints, but a no flow adhesive without fluxing ability and without added flux may not form suitable joints.

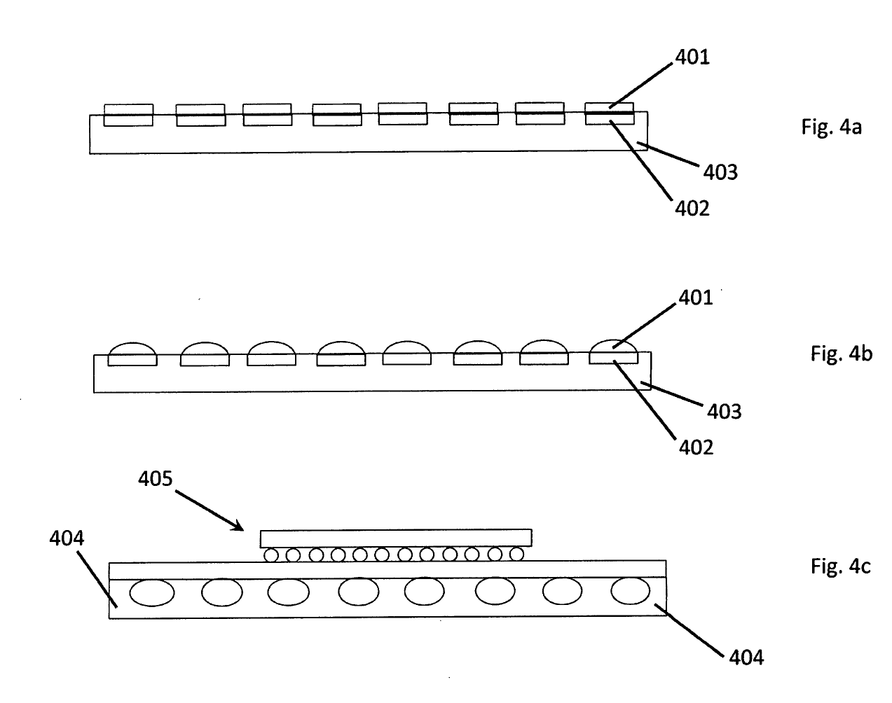

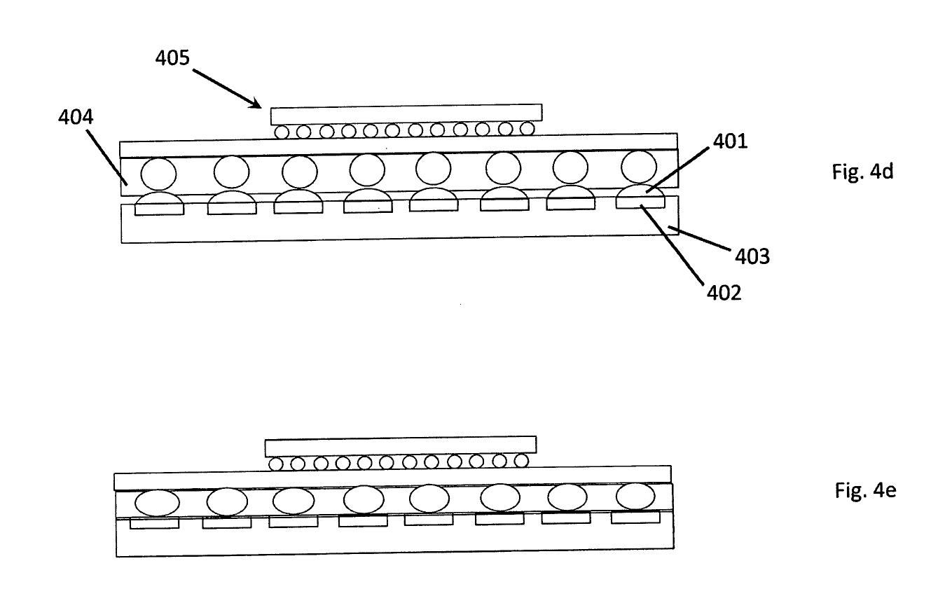

FIGS. 4a through 4e show another process in which a filler based no flow adhesive 404 is applied to the underside of the packaged die 405 rather than the motherboard. Here, as with the processes of FIG. 2a/3a and 2b/3b, as observed in FIGS. 4a and 4b, solder paste 401 is printed on the pads 402 of a planar board 403 and then reflowed to tin the planar board pads 402. Flux may then be applied to the tinned pads (as with FIG. 3c) or no such flux may be applied (as presented in FIGS. 4b through 4e. Unlike FIGS. 2c and 3d, however, instead of applying the filler based no flow adhesive 404 on the planar board 403, the die package 405 balls are dipped into a bath of filler based no flow adhesive to coat the balls with the adhesive as observed in FIG. 4c. The packaged die 405 with adhesive coated solder balls is then mounted to the planar board 403, as observed in FIG. 4d. The solder balls are then reflowed as observed in FIG. 4e.

Although the above discussions have been directed to a second level interconnect (packaged die to planar board), it should be noted that the above teaching can also be applied to third level interconnects as well (planar board to planar board). In this case the packaged die of the above teachings is replaced by a planar board having a packaged semiconductor die mounted to it.

The filler based no flow adhesive may have various characteristics to promote any of the manufacturing processes described above. For instance in one embodiment, the adhesive may have a viscosity within a range of 100-300 Pa·s at 1 RPM and 25° C. and may further be dispensable (e.g., by an Auger dispensation process) as well as printable. Moreover, the adhesive may additionally exhibit a viscosity of 2-10 Pa·s at 1 RMP and 100-180° C. to be sufficiently malleable during solder ball reflow to properly set the mechanical joint between structures, while, at the same time, not spread into the pad area (substantially only spread around the pad regions).

Additionally, in various embodiments, the cure kinetics, which characterizes how much the adhesive hardens during the solder ball reflow process, should be greater than 50% of total cure at 170° C.-180° C. for a two minute time period. Generally, an initial slow cure (to favor solder ball joint formation) followed by a fast cure (to seal the structures shortly after joint formation) is desirable. In an embodiment, the curing that occurs to the adhesive during solder ball reflow should be sufficient to completely cure the adhesive (e.g., no second adhesive curing step is performed). Voiding/outgassing during should be minimal during solder ball reflow.

In an embodiment, the Thixotropic index of the adhesive, which characterizes how less viscous the adhesive becomes if it shaken or otherwise physically agitated should be greater than 2.0 during 1 RPM to 10 RPM speed-up cycles at 25° C. Again, a higher index will generally be characteristic of adhesives that will not substantially spread during the reflow of the solder balls.

In an embodiment, the glass transition temperature (Tg) of the adhesive, which is the temperature at which the adhesive changes from a hard substance to a more rubber-like substance should be 120° C. or higher.

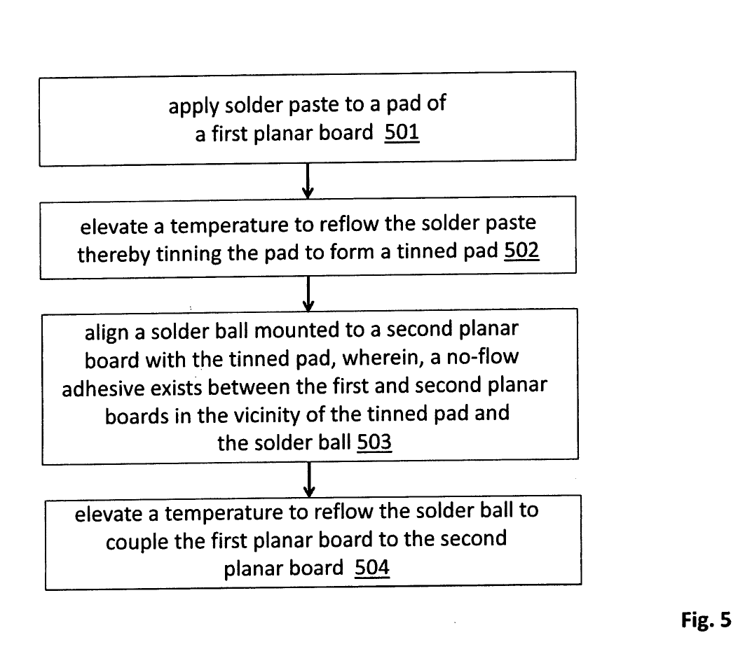

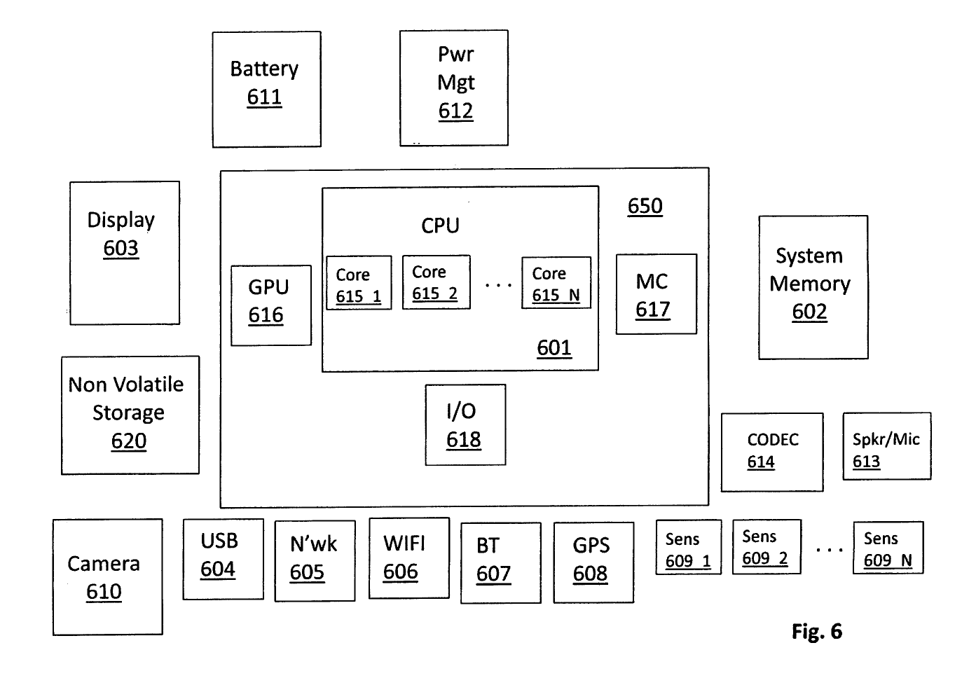

FIG. 5 shows a methodology described above. As observed in FIG. 5 the methodology includes applying solder paste to a pad of a first planar board 501. The method also includes elevating a temperature to reflow the solder paste thereby tinning the pad to form a tinned pad 502. The method also includes aligning a solder ball mounted to a second planar board with the tinned pad, wherein, a no-flow adhesive exists between the first and second planar boards in the vicinity of the tinned pad and the solder ball 503. The method also includes elevating a temperature to reflow the solder ball to couple the first planar board to the second planar board 504.

FIG. 6 shows a depiction of an exemplary computing system 600 such as a personal computing system (e.g., desktop or laptop) or a mobile or handheld computing system such as a tablet device or smartphone, or, a larger computing system such as a server computing system. The computing system may contain a board to board interface as described above.

As observed in FIG. 6, the basic computing system may include a central processing unit 601 (which may include, e.g., a plurality of general purpose processing cores and a main memory controller disposed on an applications processor or multi-core processor), system memory 602, a display 603 (e.g., touchscreen, flat-panel), a local wired point-to-point link (e.g., USB) interface 04, various network I/O functions 605 (such as an Ethernet interface and/or cellular modem subsystem), a wireless local area network (e.g., WiFi) interface 606, a wireless point-to-point link (e.g., Bluetooth) interface 607 and a Global Positioning System interface 608, various sensors 609_1 through 609_N (e.g., one or more of a gyroscope, an accelerometer, a magnetometer, a temperature sensor, a pressure sensor, a humidity sensor, etc.), a camera 610, a battery 611, a power management control unit 612, a speaker and microphone 613 and an audio coder/decoder 614.

An applications processor or multi-core processor 650 may include one or more general purpose processing cores 615 within its CPU 601, one or more graphical processing units 616, a memory management function 617 (e.g., a memory controller) and an I/O control function 618. The general purpose processing cores 615 typically execute the operating system and application software of the computing system. The graphics processing units 616 typically execute graphics intensive functions to, e.g., generate graphics information that is presented on the display 603. The memory control function 617 interfaces with the system memory 602. The system memory 602 may be a multi-level system memory.

Each of the touchscreen display 603, the communication interfaces 604-607, the GPS interface 608, the sensors 609, the camera 610, and the speaker/microphone codec 613, 614 all can be viewed as various forms of I/O (input and/or output) relative to the overall computing system including, where appropriate, an integrated peripheral device as well (e.g., the camera 610). Depending on implementation, various ones of these I/O components may be integrated on the applications processor/multi-core processor 650 or may be located off the die or outside the package of the applications processor/multi-core processor 650.

Embodiments of the invention may include various processes as set forth above. The processes may be embodied in machine-executable instructions. The instructions can be used to cause a general-purpose or special-purpose processor to perform certain processes. Alternatively, these processes may be performed by specific hardware components that contain hardwired logic for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

In the preceding specification, a method has been described. The method includes applying solder paste to a pad of a first planar board and elevating a temperature to reflow the solder paste thereby tinning the pad to form a tinned pad. The method further includes aligning a solder ball mounted to a second planar board with the tinned pad, wherein, a no-flow adhesive exists between the first and second planar boards in the vicinity of the tinned pad and the solder ball. The method also includes elevating a temperature to reflow the solder ball to couple the first planar board to the second planar board.

In an embodiment the second planar board is a substrate of a packaged semiconductor die. In an embodiment the coupling of the first and second planar boards is a second level interconnect. In an embodiment, the method includes applying, after the tinning of the pad, the no-flow adhesive to a surface of the first planar board having the tinned pad. In an embodiment the no-flow adhesive is applied by any of: printing said no-flow adhesive on said first planar board; spraying said no-flow adhesive on said first planar board; dipping said first planar board into said no-flow adhesive; dispensing said no-flow adhesive on said first planar board.

In an embodiment the method further includes applying the no-flow adhesive to a surface of the second planar board having the solder ball. In this particular embodiment the no-flow adhesive is applied by any of: printing said no-flow adhesive on said first planar board; spraying said no-flow adhesive on said first planar board; dipping said first planar board into said no-flow adhesive; dispensing said no-flow adhesive on said first planar board.

In an embodiment the method includes applying flux to the tinned pad prior to the aligning.

An apparatus has been described above that includes a first planar board to second planar board interface having a reflowed solder electrical connection structure between the first and second boards and a no flow adhesive. The reflowed solder electrical connection structure includes a reflowed solder ball and a reflowed tinned pad. In an embodiment the first board is a semiconductor package substrate. In an embodiment the first and second planar boards are planar boards other than a semiconductor package substrate. In an embodiment there is flux between the reflowed solder ball and the reflowed tinned pad.

In an embodiment the reflowed solder structure electrical connection is substantially free of filler material of the no flow adhesive. In an embodiment the no flow adhesive is applied to the first board where the first board is a planar board other than a semiconductor package substrate. In an embodiment the first planar board to second planar board interface is a third level interconnect.

A computing system has been described above that includes a plurality of processing cores and a memory controller coupled to the plurality of processing cores. The computing system includes a system memory coupled to the memory controller. The computing system includes a first planar board to second planar board interface comprising a reflowed solder electrical connection structure between the first and second boards and a no flow adhesive. The reflowed solder electrical connection structure includes a reflowed solder ball and a reflowed tinned pad.

In an embodiment of the computing system the first board is a semiconductor package substrate. In an embodiment of the computing system the first and second boards are planar boards other than a semiconductor package substrate. In an embodiment of the computing system there is flux between the reflowed solder ball and the reflowed tinned pad. In an embodiment the reflowed solder structure electrical connection is substantially free of filler material of the no flow adhesive.

1.-20. (canceled)

21. A method, comprising:
applying solder paste to a pad of a first planar board;
elevating a temperature to reflow said solder paste thereby tinning said pad to form a tinned pad;
aligning a solder ball mounted to a second planar board with said tinned pad, wherein, a no-flow adhesive exists between said first and second planar boards in the vicinity of said tinned pad and said solder ball; and,
elevating a temperature to reflow said solder ball to couple said first planar board to said second planar board.

22. The method of claim 21 wherein said second planar board is a substrate of a packaged semiconductor die.

23. The method of claim 21 wherein said coupling of said first and second planar boards is a second level interconnect.

24. The method of claim 21 further comprising:
applying, after said tinning of said pad, said no-flow adhesive to a surface of said first planar board having said tinned pad.

25. The method of claim 21 wherein said no-flow adhesive is applied by any of:
printing said no-flow adhesive on said first planar board;
spraying said no-flow adhesive on said first planar board;
dipping said first planar board into said no-flow adhesive;
dispensing said no-flow adhesive on said first planar board.

26. The method of claim 21 further comprising:
applying said no-flow adhesive to a surface of said second planar board having said solder ball.

27. The method of claim 26 wherein said no-flow adhesive is applied by any of:
printing said no-flow adhesive on said first planar board;
spraying said no-flow adhesive on said first planar board;
dipping said first planar board into said no-flow adhesive;
dispensing said no-flow adhesive on said first planar board.

28. The method of claim 21 further comprising applying flux to said tinned pad prior to said aligning.

29. An apparatus, comprising:
a first planar board to second planar board interface comprising a reflowed solder electrical connection structure between said first and second boards and a no flow adhesive, said reflowed solder electrical connection structure including a reflowed solder ball and a reflowed tinned pad.

30. The apparatus of claim 29 wherein said first board is a semiconductor package substrate.

31. The apparatus of claim 29 wherein said first and second planar boards are planar boards other than a semiconductor package substrate.

32. The apparatus of claim 29 further comprising flux between said reflowed solder ball and said reflowed tinned pad.

33. The apparatus of claim 29 wherein said reflowed solder structure electrical connection is substantially free of filler material of said no flow adhesive.

34. The apparatus of claim 29 wherein said no flow adhesive is applied to said first board, said first board being a planar board other than a semiconductor package substrate.

35. The apparatus of claim 29 wherein said first planar board to second planar board interface is a third level interconnect.

36. A computing system, comprising:
a plurality of processing cores;
a memory controller coupled to the plurality of processing cores;
a system memory coupled to the memory controller; and,
a first planar board to second planar board interface comprising a reflowed solder electrical connection structure between said first and second boards and a no flow adhesive, said reflowed solder electrical connection structure including a reflowed solder ball and a reflowed tinned pad.

37. The computing system of claim 36 wherein said first board is a semiconductor package substrate.

38. The computing system of claim 36 wherein said first and second boards are planar boards other than a semiconductor package substrate.

39. The computing system of claim 36 further comprising flux between said reflowed solder ball and said reflowed tinned pad.

40. The computing system of claim 36 wherein said reflowed solder structure electrical connection is substantially free of filler material of said no flow adhesive.
